(19) United States
(12) Patent Application Publication
(10) Pub. No.: US 2017/0098681 A1
(43) Pub. Date: Apr. 6, 2017

(54) IMAGE SENSOR AND METHOD FOR FABRICATING THE SAME

(71) Applicant: SK hynix Inc., Gyeonggi-do (KR)

(72) Inventors: Yeoun-Soo KIM, Gyeonggi-do (KR); Chang-Su PARK, Gyeonggi-do (KR); Young-Su LEE, Gyeonggi-do (KR); Seong-Hun KANG, Gyeonggi-do (KR)

(21) Appl. No.: 14/992,455

(22) Filed: Jan. 11, 2016

(30) Foreign Application Priority Data
Oct. 5, 2015 (KR) 10-2015-0139455

(51) Int. Cl. H01L 27/146

(52) U.S. Cl. CPC H01L 27/14656; H01L 27/14689

(57) ABSTRACT

Provided is an image sensor having improved characteristics. An image sensor in accordance with an embodiment of the present invention may include first and second photoelectric conversion elements formed in a substrate, wherein the first photoelectric conversion element has a first impurity region; a device isolation trench formed in the substrate and between the first and the second photoelectric conversion elements, wherein a sidewall of the device isolation trench is in contact with the first impurity region; and an epitaxial layer filling the device isolation trench, and having different conductivity from the first impurity region.

### CROSS-REFERENCE TO RELATED APPLICATIONS

The present application claims priority of Korean Patent Application No. 10-2015-0139455, filed on Oct. 5, 2015, which is herein incorporated by reference in its entirety.

### BACKGROUND

Exemplary embodiments of the present invention relate to a semiconductor device manufacturing technology, and more particularly, to an image sensor including a device isolation structure and a method for fabricating the same.

An image sensor converts an optical image into electrical signals. Due to the development of the computer industry and the communication industry, the demand for image sensors with improved performance has increased in various fields such as digital cameras, camcorders, personal communication systems (PCS), game machines, security cameras, medical micro-cameras, and robots.

### SUMMARY

Various embodiments are directed to an image sensor having improved performance and a method for fabricating the same.

In an embodiment, an image sensor may include first and second photoelectric conversion elements formed in a substrate, wherein the first photoelectric conversion element has a first impurity region; a device isolation trench formed in the substrate and between the first and the second photoelectric conversion elements, wherein a sidewall of the device isolation trench is in contact with the first impurity region; and an epitaxial layer filling the device isolation trench, and having different conductivity from the first impurity region.

The epitaxial layer may further extend to over the first and the second photoelectric conversion elements. The epitaxial layer may have a higher impurity doping concentration than the first impurity region. The substrate and the epitaxial layer may include the same material as each other. Each of the substrate and the epitaxial layer may include a single crystal silicon-containing material. A conductivity type of the first impurity region may be an N-type, and a conductivity type of the epitaxial layer may be a P-type.

In another embodiment, a method for fabricating an image sensor may include forming first and second photoelectric conversion elements in a substrate, wherein the first photoelectric conversion element has a first impurity region; forming a device isolation trench by selectively etching the substrate to isolate the first and the second photoelectric conversion elements, and a sidewall of the device isolation trench is in contact with the first impurity region; and forming an epitaxial layer by epitaxial growth in the device isolation trench, wherein the epitaxial layer and the first impurity region have different conductivity from each other.

The epitaxial layer may further extend to over the first and the second photoelectric conversion elements. The epitaxial layer may have a higher impurity doping concentration than the first impurity region. The substrate and the epitaxial layer may include the same material as each other. Each of the substrate and the epitaxial layer may include a single crystal silicon-containing material. A conductivity type of the first impurity region may be an N-type, and a conductivity type of the epitaxial layer may be a P-type.

### BRIEF DESCRIPTION OF THE DRAWINGS

FIG. 1 is a block diagram schematically illustrating an image sensor in accordance with an embodiment of the present invention.

FIG. 2 is a plan view illustrating a portion of a pixel array of an image sensor in accordance with an embodiment of the present invention.

FIG. 3 is a cross-sectional view illustrating an image sensor in accordance with an embodiment of the present invention and taken along the line A-A′ shown in FIGS. 1 and 2.

FIG. 4 is a cross-sectional view illustrating an image sensor in accordance with another embodiment of the present invention and taken along the line A-A′ shown in FIGS. 1 and 2.

FIGS. 5A to 5C are cross-sectional views illustrating a method for fabricating an image sensor in accordance with an embodiment of the present invention and taken along the line A-A′ shown in FIGS. 1 and 2.

FIG. 6 is a diagram schematically illustrating an electronic device including an image sensor shown n FIG. 1.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case in which the first layer is formed directly on the second layer or the substrate but also a case in which a third layer exists between the first layer and the second layer or the substrate.

The following embodiments of the present invention may provide an image sensor having improved performance and a method for fabricating the same. Here, the image sensor having improved performance may mean an image sensor having an increased fill factor. The fill factor means a ratio of a photoelectric conversion area with respect to a total area of a unit pixel. As the fill factor increases, a sensitivity of the image sensor may be improved. Moreover, the image sensor having improved performance may mean an image sensor has a low electrical cross-talk and a blooming phenomenon among adjacent unit pixels.

For that purpose, provided is an image sensor including a device isolation structure formed in a substrate, and a junction-isolated from an impurity region of a photoelectric conversion element.

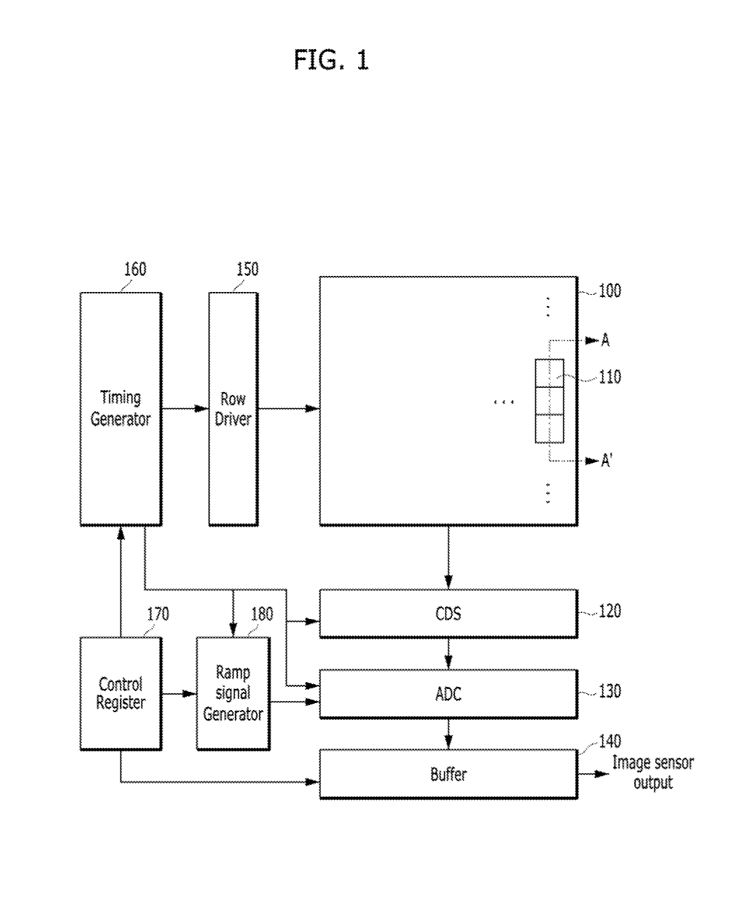

FIG. 1 is a block diagram schematically illustrating an image sensor in accordance with an embodiment of the present invention. As shown in FIG. 1, the image sensor in accordance with the embodiment of the present invention may include a pixel array 100 in which a plurality of unit pixels 110 are arranged in a matrix shape, a correlated double sampling (CDS) 120, an analog digital converter (ADC) 130, a buffer 140, a row driver 150, a timing generator 160, a control register 170, and a ramp signal generator 180.

The timing generator 160 may generate one or more control signals for controlling the row driver 150, the CDS unit 120 the ADC 130, and the ramp signal generator 180. The control register 170 may generate one or more control signals for controlling the ramp signal generator 180, the timing generator 160, and the buffer 140.

The row driver 150 may drive the pixel array 100 row by row. For example, the row driver 150 may generate a select signal for selecting any one row line of a plurality of row lines. Each of the unit pixels 110 may sense incident light and output an image reset signal and an image signal to the CDS unit 120 through a column line. The CDS unit 120 may perform sampling on the image reset signal and the image signal.

The ADC 130 may compare a ramp signal outputted from the ramp signal generator 180 with a sampling signal outputted from the CDS unit 120 and output a comparison signal. According to a clock signal provided from the timing generator 160, the ADC 130 may count the level transition time of the comparison signal and output the count value to the buffer 140. The ramp signal generator 180 may operate under control of the timing generator 160.

The buffer 140 may store a plurality of digital signals outputted from the ADC 130 and then sense and amplify the digital signals. Thus, the buffer 140 may include a memory (not illustrated) and a sense amplifier (not illustrated). The memory may store count values. The count values may represent signals outputted from the plurality of unit pixels 110. The sense amplifier may sense and amplify the count values outputted from the memory.

Here, as the image sensor becomes highly integrated, a size or an area of each of the plurality of unit pixels 110 and a space between unit pixels 110 are gradually decreased. Thus, deterioration of characteristics due to interference between adjacent unit pixels 110, for example, an electrical cross-talk and a blooming phenomenon, increases. In order to prevent such a problem, a device isolation structure isolating each of the unit pixels 110 may be formed in a substrate. The device isolation structure may be an impurity region or an insulating material region. The impurity region is formed by ion-implanting an impurity in the substrate. The insulating material region is formed by forming a device isolation trench in the substrate and filling the device isolation trench with an insulating material.

The device isolation structure including the impurity region to may have an advantage of preventing an electrical cross-talk and a blooming phenomenon by functioning as a potential barrier and blocking a carrier transfer among the unit pixels 110. However, since it is very difficult to control diffusion of an impurity during a forming process of the impurity region, it is difficult to increase a degree of integration of the device isolation structure. That is, due to such a drawback, a fill factor of the image sensor is not increased as much as desired. Also, characteristics may be deteriorated due to an impurity diffused during the forming process.

On the contrary, the device isolation structure including the insulating material region has an advantage of facilitating integration and improving a fill factor of the image sensor. However, there is another drawback that the insulating material region serving as the device isolation causes a dark current due to various defects present over a surface of the device isolation trench, for example, a dangling bond.

Therefore, in the following embodiments of the present invention, an image sensor includes a device isolation structure which will be described in detail with reference to drawings. The device isolation structure has advantages of both of the device isolation structure and the device isolation structure. In addition, the device isolation structure has none of the drawback described above.

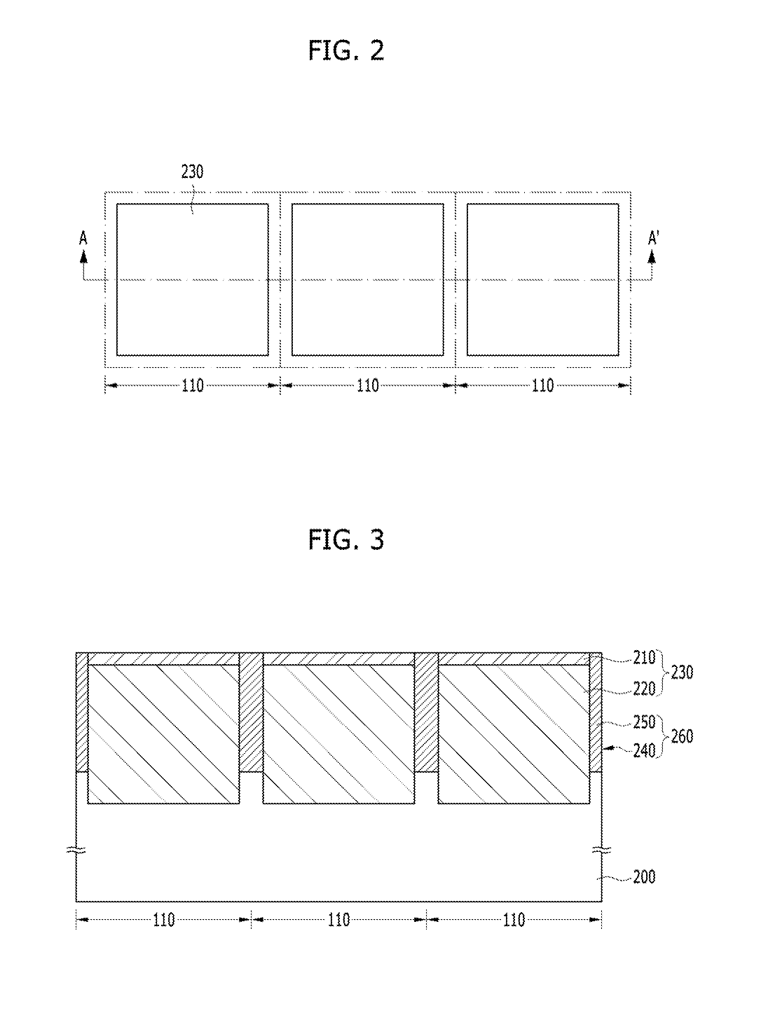

FIG. 2 is a plan view illustrating a portion of a pixel array of an image sensor in accordance with an embodiment of the present invention. FIG. 3 is a cross-sectional view illustrating an image sensor in accordance with an embodiment of the present invention and taken along the line A-A′ shown in FIGS. 1 and 2.

As shown in FIGS. 2 and 3, the image sensor in accordance with the embodiment of the present invention may include a plurality of photoelectric conversion elements 230 and a device isolation structure 260. Each of the plurality of photoelectric conversion elements 230 is formed in a substrate 200 and includes an impurity region. The device isolation structure 260 is formed in the substrate 200 and among the plurality of photoelectric conversion elements 230. The device isolation structure 260 may have a sidewall and an epitaxial layer 250. The sidewall contacts the photoelectric conversion element 230. The epitaxial layer 250 has a conductivity type different from the impurity region and gap-filling the device isolation trench 240.

The substrate 200 may include a semiconductor substrate. The semiconductor substrate may be in a single crystal state and include a silicon-containing material, That is, the substrate 200 may include a single crystal silicon-containing material. For example the substrate 200 may be a bulk silicon substrate.

The photoelectric conversion element 230 may include a photodiode formed in the substrate 200. The photodiode may include a P-type region and an N-type region. Here, the impurity region may be an N-type region. Specifically, the photoelectric conversion element 230 may have a first impurity region 210 and a second impurity region 220. The first impurity region 210 and the second impurity region 220 have different conductivity from each other and are vertically stacked. The first impurity region 210 may be a P-type region of the photodiode, and the second impurity region 220 may be an N-type region of the photodiode. The first impurity region 210 may have a smaller thickness than the second impurity region 220.

Furthermore the first impurity region 210 may be formed, at a different position depending on a position of an incident surface where an incident light is introduced into the photoelectric conversion element 230. Specifically, in an embodiment, a front side of the substrate 200 functions as an incident surface. However, the present invention is not limited thereto That is, when a back side of the substrate 200 functions as an incident surface, the first impurity region 210 may be formed on an opposite side to a position shown in FIG. 3 and located adjacent to the back side of the substrate 200.

The device isolation trench 240 may be formed in the substrate 200 between the photoelectric conversion elements 230. A sidewall of the device isolation trench 240 contacts the second impurity region 220 of the photoelectric conversion element 230. This contributes to improving a fill factor of the image sensor.

The epitaxial layer 250 may include the same silicon-containing material as the substrate 200. For example, the epitaxial layer 250 may be a silicon epitaxial layer. The epitaxial layer 250 filling the device isolation trench 240 may have a conductivity type different from the second impurity region 220 of the photoelectric conversion element 230 and contact the second impurity region 220. For example, the epitaxial layer 250 may be a silicon epitaxial layer doped with a P-type impurity. Accordingly, the epitaxial layer 250 and the second impurity region 220 of the photoelectric conversion element 230 may be junction-isolated from each other.

Here, the epitaxial layer 250 may have a higher impurity doping concentration than the second impurity region 220 in order to improve an electrical characteristic and junction isolation of the photoelectric conversion element 230. Thus, the epitaxial layer 250 may function as a potential barrier and block a carrier transfer between the unit pixels 110 to prevent an electrical cross-talk and a blooming phenomenon.

Moreover, the epitaxial layer 250 formed by epitaxial growth may suppress diffusion of an impurity since the doped impurity is activated simultaneously while the epitaxial layer 250 is formed. That is, it is possible to prevent deterioration of characteristics due to diffusion of an impurity. In addition, since various defects are present over a surface of the device, the isolation trench 240 may be recovered during the epitaxial growth. Thus, deterioration of characteristics due to the defects, for example, a dark current, may be prevented.

For reference, in a conventional device isolation structure, there is a limit to improving a fill factor of the image sensor since the impurity region and the insulating material region are spaced apart from the photoelectric conversion element to prevent diffusion of an impurity and defects occurring at a surface of the device isolation trench. However, in the image sensor in accordance with an embodiment of the present invention, a sidewall of the device isolation trench 240 contacts the second impurity region 220 of the photoelectric conversion element 230, and the epitaxial layer 250 can suppress diffusion of an impurity and recover defects. Thus, a fill factor of the image sensor may be easily improved.

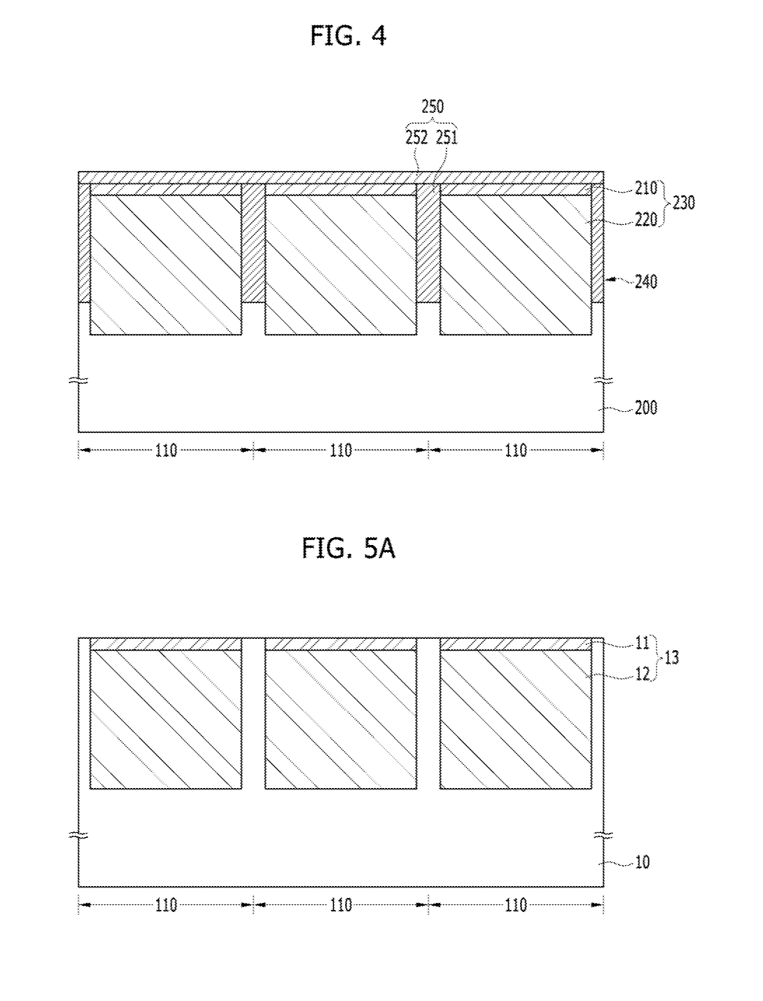

FIG. 4 is a cross-sectional view illustrating an image sensor in accordance with another embodiment of the present invention and taken along the line A-A′ shown in FIGS. 1 and 2. Here, the same elements as those of FIG. 3 are denoted by the same reference numerals as those of FIG. 4.

A shown in FIG. 4 the image sensor in accordance with another embodiment may include a plurality of photoelectric conversion elements 230. Each of the photoelectric conversion elements 230 is formed in a substrate 200 and includes an impurity region and a device isolation structure 260. The device isolation structure 260 is formed in the substrate 200 and between the photoelectric conversion elements 230. The device isolation structure 260 may include a device isolation trench 240, a first portion epitaxial layer 251, and a second portion epitaxial layer 252. The device isolation trench 240 is formed in the substrate 200 and between the photoelectric conversion elements 230. A sidewall of the device isolation trench 240 contacts the impurity region. The first portion epitaxial layer 251 has a conductivity type different from the impurity region and fills in the device isolation trench 240. The second portion epitaxial layer 252 extends from the first portion epitaxial layer 251 to the substrate 200 to cover the photoelectric conversion element 230.

The substrate 200 may include a semiconductor substrate. The semiconductor substrate may be a single crystal state and include a silicon-containing material. That is, the substrate 200 may include a single crystal silicon-containing material. For example, the substrate 200 may be a bulk silicon substrate.

The photoelectric conversion element 230 may include a photodiode formed in the substrate 200. The photodiode may include a P-type region and an N-type region. Here, the impurity region may be an N-type region. Specifically, the photoelectric conversion element 230 may have a first impurity region 210 and a second impurity region 220. The first impurity region 210 and the second impurity region 220 have different types of conductivity from each other and are vertically stacked. The first impurity region 210 may be a P-type region of the photodiode, and the second impurity region 220 may be an N-type region of the photodiode. The first impurity region 210 may have a smaller thickness than the second impurity region 220.

The device isolation trench 240 may be formed in the substrate 200 and between the photoelectric conversion elements 230. A sidewall of the device isolation trench 240 contacts the second impurity region 220 of the photoelectric conversion element 230. This can improve a fill factor of the image sensor.

The epitaxial layer 250 and the first and second portions may include the same silicon-containing material as the substrate 200. For example, the epitaxial layer 250 may be a silicon epitaxial layer. The epitaxial layer 250 may have a conductivity type different from the second impurity region 220 of the photoelectric conversion element 230. For example, the epitaxial layer 250 may be a silicon epitaxial layer doped with a P-type impurity.

The first portion epitaxial layer 251 may contact the second impurity region 220. The first portion epitaxial layer 251 and the second impurity region 220 of the photoelectric conversion element 230 may be junction-isolated from each other. Here, the first portion epitaxial layer 251 may have a higher impurity doping concentration than the second impurity region 220 in order to improve an electrical characteristic and junction isolation of the photoelectric conversion element 230. Thus, the first portion epitaxial layer 251 may function as a potential barrier and block a carrier transfer between the unit pixels 110 to prevent an electrical cross-talk and a blooming phenomenon.

Moreover, the first portion epitaxial layer 251 may be formed by epitaxial growth and may suppress diffusion of an impurity since the doped impurity is activated simultaneously during the epitaxial growth. That is, it is possible to prevent deterioration of characteristics due to diffusion of an impurity. In addition, various defects which may be present over a surface of the device isolation trench 240 may be recovered during the epitaxial growth. Thus, deterioration of characteristics due to the defects, for example, a dark current, may be prevented.

The second portion epitaxial layer 252 may serve to prevent a dark current caused by defects over a surface of the substrate 200. The second portion epitaxial layer 252 and the first portion epitaxial layer 251 may be formed by the same process as each other and form an integrated epitaxial layer 250.

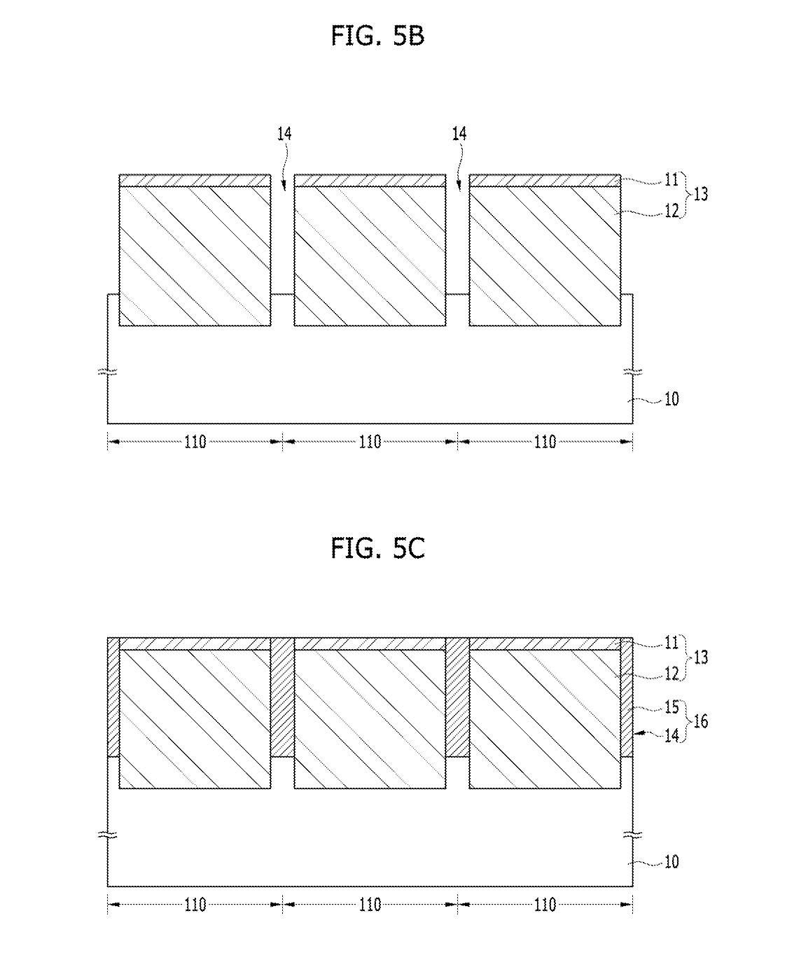

FIGS. 5A to 5C are cross-sectional views illustrating a method for fabricating an image sensor in accordance with an embodiment of the present invention and taken along the line A-A′ shown in FIGS. 1 and 2. Here, an example of a method for fabricating the image sensor shown in FIG. 3 will be described.

As shown in FIG. 5A, a photoelectric conversion element 13 may be formed in a substrate 10 of each of a plurality of unit pixels 110. The substrate 10 may include a single crystal silicon-containing material. For example, the substrate 10 may be a bulk silicon substrate.

The photoelectric conversion element 13 may include a photodiode. The photodiode may have a first impurity region 11 doped with a P-type impurity and a second impurity region 12 doped with an N-type impurity. The first impurity region 11 and the second impurity region 12 are vertically stacked. The first impurity region 11 may have a smaller thickness than the second impurity region 12. The first impurity region 11 and the second impurity region 12 may be formed by an ion implantation process, respectively.

As shown in FIG. 5B, a device isolation trench 14 may be formed by selectively etching the substrate 10 between the photoelectric conversion elements 13 Here, the device isolation trench 14 may be formed so that a sidewall of the device isolation trench 14 contacts the photoelectric conversion element 13. Particularly, the sidewall of the device isolation trench 14 may contact the second impurity region 12 of the photoelectric conversion element 13. Forming the device isolation trench 14 may be performed by a dry etch process.

Furthermore, various defects occurring in the etch process may exist over a surface of the device isolation trench 14 and such defects may function as a source of a dark current.

As shown in FIG. 5C, an epitaxial layer 15 may fill the device isolation trench 14 through an epitaxial growth. The epitaxial layer 15 may be formed of the same silicon-containing material as the substrate 10. For example, the epitaxial layer 15 may be formed as a silicon epitaxial layer.

During the process for forming the epitaxial layer 15, an impurity having a conductivity type different from the second impurity region 12 of the photoelectric conversion element 13 may be in-situ doped so that the epitaxial layer 15 may function as a device isolation structure 16. Accordingly, a conductivity type of the epitaxial layer 15 may be a P-type, and thus, junction isolation of the epitaxial layer 15 and the second impurity region 12 of the photoelectric conversion element 13 may be implemented. Here, the epitaxial layer 15 may have a higher impurity doping concentration than the second impurity region 12 in order to improve an electrical characteristic and junction isolation of the photoelectric conversion element 13.

The epitaxial layer 15 formed by the process described above may function as a potential barrier, and block a carrier transfer between the unit pixels 110 to prevent an electrical cross-talk and a blooming phenomenon. Moreover, the epitaxial layer 15 formed by epitaxial growth may suppress diffusion of an impurity since the doped impurity is activated simultaneously during the epitaxial growth, That is, it is possible to prevent deterioration of characteristics due to diffusion of an impurity. In addition, since various defects present over a surface of the device isolation trench may be recovered during the epitaxial growth, deterioration of characteristics due to the defects such as a dark current may be prevented. Then, the image sensor may be completely fabricated by known technologies.

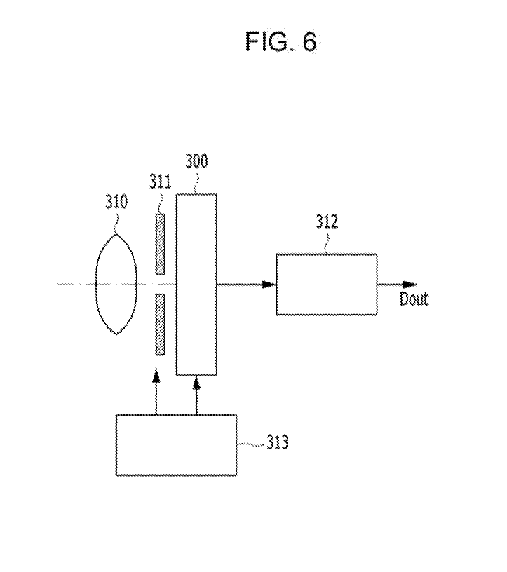

The image sensor in accordance with an embodiment of the present invention may be used in various electronic devices or systems. Hereafter, the image sensor in accordance with an embodiment of the present invention which is applied to a camera will be described with reference to FIG. 6.

FIG. 6 is a diagram schematically illustrating an electronic device including an image sensor shown in FIG. 1. Referring to FIG. 6 the electronic device including the image sensor in accordance with an embodiment of the present invention may be a camera capable of taking a still image or moving image. The electronic device may include an optical system or optical lens 310, a shutter unit 311 a driving unit 313 for controlling/driving the image sensor 300, the shutter unit 311, and a signal processing unit 312.

The optical system 310 may guide image light from an object to the pixel array 100 of the image sensor 300. The optical system 310 may include a plurality of optical lenses. The shutter unit 311 may control a light irradiation period and a light shield period for the image sensor 300. The driving unit 313 may control a transmission operation of the image sensor 300 and a shutter operation of the shutter unit 311. The signal processing unit 312 may process signals outputted from the image sensor 300 in various manners. The processed image signals Dout may be stored in a storage medium such as a memory or outputted to a monitor or the like.

In accordance with the present technology, it is possible to improve a fill factor of an it mage sensor by making a sidewall of a device isolation trench to contact with a photoelectric conversion element and filling the device isolation trench with an epitaxial layer. Moreover, an electrical cross-talk, a blooming phenomenon, and a dark current may be prevented.

While the present invention has been described with respect to the specific embodiments, it will be apparent to those skilled in the art that various changes and modifications may be made without departing from the spirit and scope of the invention as defined in the following claims.

What is claimed is:

1. An image sensor comprising:
first and second photoelectric conversion elements formed in a substrate, wherein the first photoelectric conversion element has a first impurity region;
a device isolation trench formed in the substrate and between the first and the second photoelectric conversion elements, wherein a sidewall of the device isolation trench is in contact with the first impurity region; and
an epitaxial layer filling the device isolation trench, and having different conductivity from the first impurity region.

2. The image sensor of claim 1, wherein the epitaxial layer further extends to over the first and the second photoelectric conversion elements.

3. The image sensor of claim 1, wherein the epitaxial layer has a higher impurity doping concentration than the first impurity region.

4. The image sensor of claim 1, wherein the substrate and the epitaxial layer comprise the same material as each other.

5. The image sensor o claim wherein each of the substrate and the epitaxial layer comprises a single crystal silicon-containing material.

6. The image sensor of claim 1 wherein a conductivity type of the first impurity region is an N-type, and a conductivity type of the epitaxial layer is a P-type.

7. A method for fabricating an image sensor comprising:
forming first and second photoelectric conversion elements in a substrate, wherein the first photoelectric conversion element has a first impurity region;
forming a device isolation trench by selectively etching the substrate to isolate the first and the second photoelectric conversion elements, and a sidewall of the device isolation trench is in contact with the first impurity region; and
forming an epitaxial layer by epitaxial growth in the device isolation trench, wherein the epitaxial layer and the first impurity region have different conductivity from each other.

8. The method of claim 7,
wherein the epitaxial layer further extends to over the first and the second photoelectric conversion elements.

9. The method of claim 7, wherein the epitaxial layer has a higher impurity doping concentration than the first impurity region.

10. The method of claim 7, wherein the substrate and the epitaxial layer comprise the same material as each other.

11. The method of claim 7, wherein each of the substrate and the epitaxial layer comprises a single crystal silicon-containing material.

12. The method of claim 7, wherein a conductivity type of the first impurity region is an N-type, and a conductivity type of the epitaxial layer is a P-type.
